(19) United States
(12) Patent Application Publication
(10) Pub. No.: US 2021/0257395 A1
(43) Pub. Date: Aug. 19, 2021

(54) METHOD FOR SILICON NANOSENSOR MANUFACTURING AND INTEGRATION WITH CMOS PROCESS

(71) Applicant: Silterra Malaysia Sdn. Bhd., Kulim (MY)

(72) Inventors: Saw Li Lee, Kulim (MY); Arjun Kumar Kantimahanti, Kulim (MY); Seok Man Yun, Kulim (MY); Seng Jie Sia, Kulim (MY); Eng Pheow Tan, Kulim (MY)

(73) Assignee: Silterra Malaysia Sdn. Bhd., Kulim (MY)

(21) Appl. No.: 16/597,463

(22) Filed: Oct. 9, 2019

(30) Foreign Application Priority Data
Mar. 26, 2019 (MY) PI 2019001669

(51) Int. Cl. H01L 27/144; H01L 31/0352; H01L 31/028; H01L 31/18

(52) U.S. Cl. CPC H01L 27/1443; H01L 31/1804; H01L 31/028; H01L 31/035227

(57) ABSTRACT

A method for producing a silicon nanosensor integrated with advanced complementary metal oxide semiconductor (CMOS) logic circuit having gate length (Lg) of less than 0.25 μm, comprising the steps of: allocating a silicon nanosensor region and a CMOS logic circuit region on one bulk silicon substrate; forming silicon nanowires at the allocated nanosensor region while shielding the CMOS logic circuit region; applying a layer of protecting hardmask on the substrate such that the hardmask acts as an extra protection layer to the nanosensor region while acting as a hardmask for CMOS logic circuit formation process thereinafter; subjecting the substrate to selective etching to form trenches, filling the trenches with silicon oxide and subjecting the substrate to chemical mechanical planarization; and removing the hardmask from the substrate in a region-by-region manner, in which the nanosensor region remains unexposed while removing hardmark from the CMOS logic circuit region, and vice versa.

### CROSS-REFERENCE TO RELATED APPLICATION

The instant application claims priority to Malaysia Patent Application Ser. No. PI 2019001669 filed Mar. 26, 2019, the entire specification of which is expressly incorporated herein by reference.

### FIELD OF THE INVENTION

The present invention relates generally to a method for producing a silicon nanosensor and more particularly to a method for producing a silicon nanosensor whereby the steps in producing the nanosensor are integrated into an advanced complementary metal oxide semiconductor (CMOS) fabrication process with good compatibility.

### BACKGROUND OF THE INVENTION

Silicon nanowires (SiNW) exhibit attractive characteristics that resulted their use as a sensor element in a sensor system. Recently, complementary metal oxide semiconductor (CMOS) technology is gaining popularity in the field of semiconductor device fabrication. It was found that an integrated SiNW and CMOS circuit chip would allow more design freedom with respect to interaction in the sensor system. Nevertheless, there exists problems to integrate production of SiNW with CMOS circuit. A poor integrated process can result in polysilicon remaining at trenches, or a short SiNW length.

There are mainly two ways to produce silicon nanowires: (1) a top-down method; and (2) a bottom-up method. United States Patent Application Publication No. US 2007/0105321A briefly described both methods. In order to achieve good compatibility between the SiNW and CMOS fabrication process, the top-down method which enables the device being fabricated on a thin device layer atop a silicon-on-insulator (SOI) wafer was found useful. An example of such method can be found in publication from Int. J. Electrochem. Sci., 8(2013) 10946-10960.

Another Korean Patent Application Publication No. KR20130134724A disclosed a method for manufacturing an integrated acoustic sensor comprising a silicon nanowire (SiNW) and a microphone with CMOS signal processing circuit. Such method is suitable for CMOS having gate length (Lg) more than 0.35 μm. More particularly, the SiNW is isolated from the CMOS circuit by Local Oxidation of Silicon (LOCOS) technique. However, this technique causes a lost in surface area on the silicon due to ‘bird's beak effect’. In order to avoid such drawback, an alternative approach is necessary.

### SUMMARY OF THE INVENTION

One aspect of the present invention is to provide a method for manufacturing a silicon nanosensor which comprises SiNW integrated with a CMOS circuit. More particularly, the nanosensor can be configured into a photosensor based on the circuit design and components therein.

Another aspect of the present invention is to provide a relatively cost-effective method for manufacturing a silicon nanosensor integrated with an advanced CMOS circuit having gate length (Lg) of less than 0.25 μm.

At least one of the preceding aspects is met, in whole or in part, by the present invention, in which one of the embodiments of the present invention is a method for producing a silicon nanosensor integrated with advanced complementary metal oxide semiconductor (CMOS) logic circuit having gate length (Lg) of less than 0.25 μm, the method comprising the steps of: (a) allocating a silicon nanosensor region and a complementary metal oxide semiconductor (CMOS) logic circuit region on one bulk silicon substrate; (b) forming silicon nanowires at the allocated nanosensor region while shielding the CMOS logic circuit region; (c) applying a layer of protecting hardmask on the nanosensor region and the CMOS logic circuit region such that the hardmask acts as an extra protection layer to the nanosensor region while acting as a hardmask for CMOS logic circuit formation process thereinafter; (d) subjecting the substrate to selective etching to form trenches, followed by filling the trenches with silicon oxide and subjecting the substrate to chemical mechanical planarization (CMP); and (e) removing the hardmask from the substrate in a region-by-region manner, in which the nanosensor region remains unexposed while removing hardmark from the CMOS logic circuit region, and vice versa.

Preferably, the step (e) comprises the steps of: (i) depositing an oxide layer on the substrate; (ii) shielding the nanosensor region using a photoresist; (iii) immersing the substrate in an acidic bath to remove the oxide layer at the CMOS logic circuit region; (iv) immersing the substrate in another acidic bath to remove the hardmask at the CMOS logic circuit region; (v) removing the photoresist at the nanosensor region; (vi) immersing the substrate in an acidic bath to remove the oxide layer at the nanosensor region; and (vii) immersing the substrate in another acidic bath to remove the hardmask at the nanosensor region.

Another aspect of the present invention is to provide a silicon nanosensor integrated with advanced complementary metal oxide semiconductor (CMOS) logic circuit derived from the abovementioned method.

### BRIEF DESCRIPTION OF THE DRAWINGS

FIG. 1 show fabrication steps when formation of silicon nanosensor is integrated into advanced CMOS fabrication (on the right) as compared to a general CMOS fabrication (on the left).

FIG. 2 is a schematic drawing of substrate after step (b) of the invention, in which drawing circled and labelled as A-A″ is expanded and labelled. The dotted line and arrows indicates silicon nanosensor region (labelled as “SN”) and CMOS logic circuit region (labelled as “Logic”).

FIG. 3 is a schematic drawing of substrate obtained after step (c) of the invention, in which drawing circled and labelled as A-A″ is expanded and labelled. The dotted line and arrows indicates nanosensor region (labelled as “SN”) and CMOS logic circuit region (labelled as “Logic”).

FIG. 4 is a schematic drawing of substrate obtained after STI from step (d) of the invention, in which drawing circled and labelled as A-A″ is expanded and labelled. The dotted line and arrows indicates nanosensor region (labelled as “SN”) and CMOS logic circuit region (labelled as “Logic”).

FIG. 5 is a schematic drawing of substrate obtained after CMP from step (d) of the invention, in which drawing circled and labelled as A-A″ is expanded and labelled. The dotted line and arrows indicates nanosensor region (labelled as “SN”) and CMOS logic circuit region (labelled as “Logic”).

FIG. 6 is a schematic drawing of substrate obtained after step (e) (ii) of the invention, in which drawing circled and labelled as A-A″ is expanded and labelled. The dotted line and arrows indicates nanosensor region (labelled as “SN”) and CMOS logic circuit region (labelled as “Logic”).

FIG. 7 is a schematic drawing of substrate obtained after step (e) (iv) of the invention, in which drawing circled and labelled as A-A″ is expanded and labelled. The dotted line and arrows indicates nanosensor region (labelled as “SN”) and CMOS logic circuit region (labelled as “Logic”).

FIG. 8 is a schematic drawing of substrate obtained after step (e) (vii) of the invention, in which drawing circled and labelled as A-A″ is expanded and labelled. The dotted line and arrows indicates nanosensor region (labelled as “SN”) and CMOS logic circuit region (labelled as “Logic”).

### DETAILED DESCRIPTION OF THE INVENTION

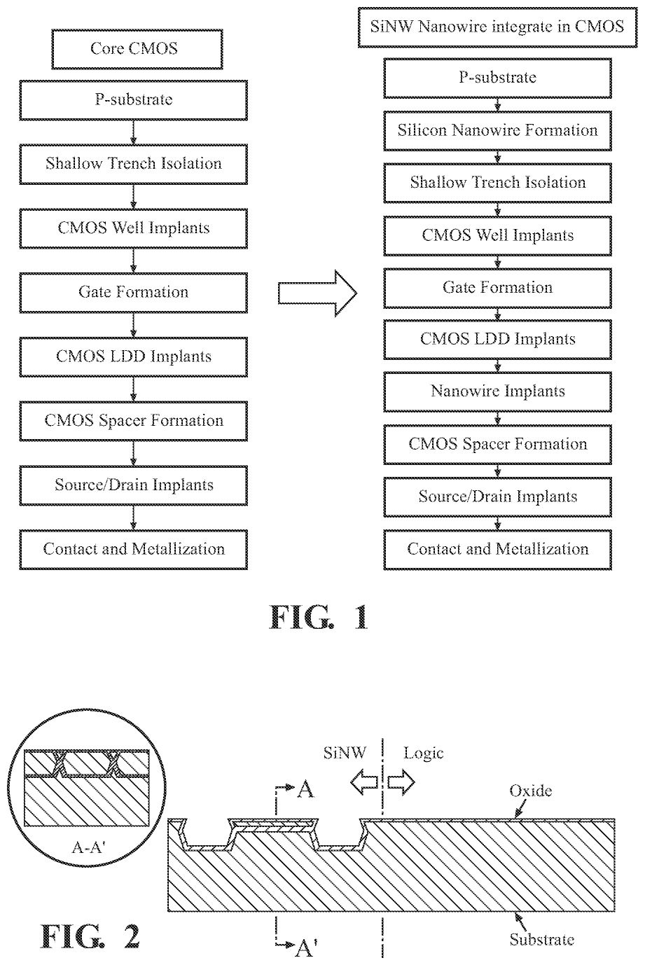

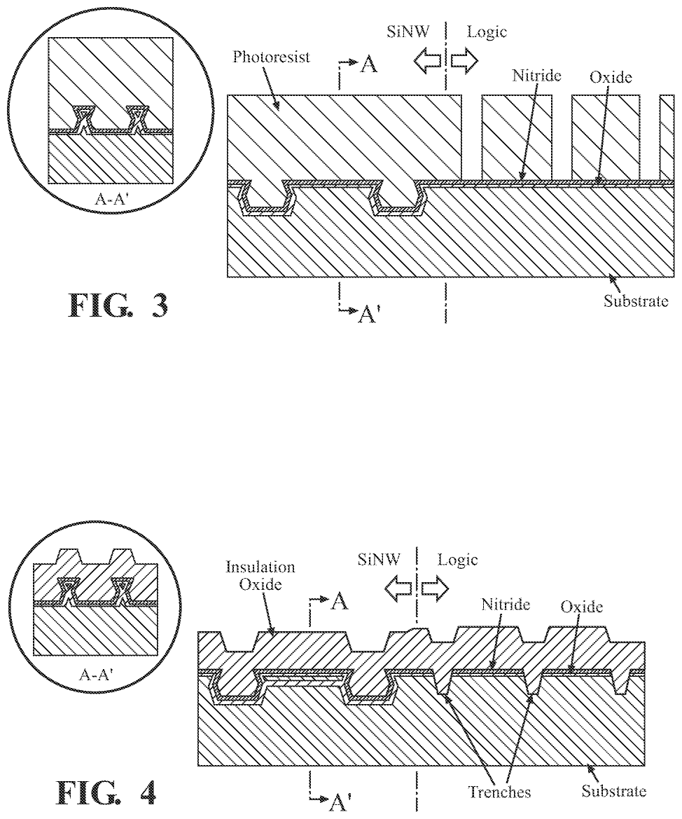

This invention relates to a method for producing a silicon nanosensor whereby the steps in producing the silicon nanosensor are integrated into an advanced complementary metal oxide semiconductor (CMOS) fabrication process with good compatibility, as shown in FIG. 1. More particularly, the nanosensor can be a photosensor, an ambient sensor or the like.

Exemplary, non-limiting embodiments of the invention will be disclosed. However, it is to be understood that limiting the description to the preferred embodiments of the invention is merely to facilitate discussion of the present invention and it is envisioned that those skilled in the art may devise various modifications without departing from the scope of the appended claim.

The present invention is a method for producing a silicon nanosensor integrated with an advanced complementary metal oxide semiconductor (CMOS) logic circuit, comprising the steps of: (a) allocating a silicon nanosensor region and a complementary metal oxide semiconductor (CMOS) logic circuit region on one bulk silicon substrate; (b) forming silicon nanowires (SiNW) at the allocated nanosensor region while shielding the CMOS logic circuit region; (c) applying a layer of protecting hardmask on the substrate such that the hardmask acts as an extra protection layer to the nanosensor region while acting as a hardmask for CMOS logic circuit formation process thereinafter; (d) subjecting the substrate to selective etching to form trenches, followed by filling the trenches with silicon oxide and subjecting the substrate to chemical mechanical planarization (CMP); and (e) removing the hardmask from the substrate in a region-by-region manner, in which the nanosensor region remains unexposed while removing hardmark from the CMOS logic circuit region, and vice versa.

In the present invention, a bulk silicon substrate, also known as a silicon wafer is preferably used as a starting material. It is preferred that the substrate used has a working surface which exhibits crystal orientation of (100) or (111). Typically, a p-type substrate is used.

The disclosed method starts with step (a) for allocating a nanosensor region and an advanced complementary metal oxide semiconductor (CMOS) logic circuit region on one bulk silicon substrate. Thereinafter, there is a step (b) for forming SiNW at the allocated nanosensor region. It shall be noted that horizontal SiNW is preferably formed, more particularly by the top-down method. In the preferred embodiment, the step (b) is conducted by dry etching the bulk silicon substrate, followed by wet etching the substrate using an anisotropic solution so as to obtain horizontal nanowires with configurations as shown in FIG. 2. General oxidant used in the prior art for the wet or dry oxidation can be applied herein. Preferably, the anisotrophic solution used can be tetramethylammonium hydroxide (TMAH), or the like.

After the formation of SiNW, there is a step of wet or dry thermal oxidizing so as to obtain a thermal oxide layer covering both regions on the substrate.

Thereinafter, there is a step of applying a layer of protecting hardmask on the thermal oxide layer aforementioned. The hardmask used can be a silicon nitride hardmask, or a silicon dioxide hardmask. Alternatively, a photoresist can be used. More preferably, a nitride hardmask is used. The nitride layer acts as an extra protection layer to the nanosensor region while acting as a hardmask for CMOS logic circuit formation process in the subsequent steps. In case where implants or salicide formation is required, the nitride layer on top of the SiNW can be removed. However, the nitride layer contacting the sidewall of the substrate shall remain.

Thereinafter, the substrate is subjected to selective etching to form trenches and filling the trenches with silicon oxide layer (FIG. 4). More particularly, there are steps of selectively etching the CMOS logic circuit region to form trenches at the substrate; and applying an insulation silicon oxide layer on both regions of the substrate (both nanosensor and CMOS logic circuit region), in which the trenches formed at CMOS logic circuit region are first grown with a liner oxide and both regions are then filled by the insulation silicon oxide. In this way, the insulation silicon oxide layer provides additional protection layer to the nanosensor region.

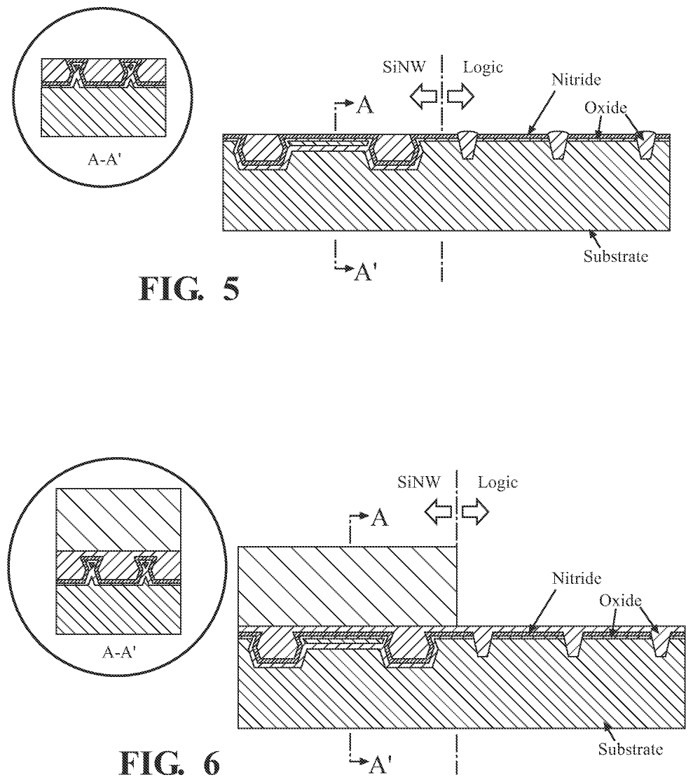

The method further comprises a step of subjecting the substrate to chemical mechanical planarization (CMP) so as to obtain a smooth planar surface on both nanosensor region and CMOS logic circuit region. FIG. 5 shows the result of step (d). Thereinafter, there is a step (e) for removing the hardmask from the substrate in a region-by-region manner (see FIGS. 6 to 8).

In the preferred embodiment, step (e) is able to remove the nitride hardmask without causing gouges at trenches. Hence, reliability issue resulted from polysilicon remaining can be avoided. More particularly, step (e) comprises the steps of:

(i) depositing an oxide layer, preferably a low temperature oxide (LTO), on the substrate;

(ii) shielding the nanosensor region using a photoresist (refer FIG. 6);

(iii) immersing the substrate in an acidic bath to remove the oxide layer at the CMOS logic circuit region;

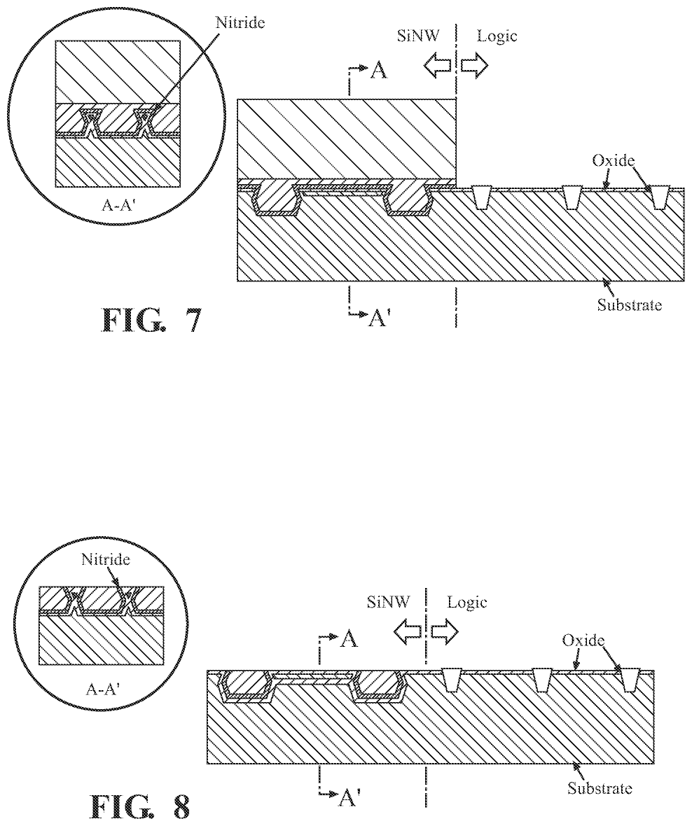

(iv) immersing the substrate in another acidic bath to remove the hardmask at the CMOS logic circuit region (see FIG. 7);

(v) removing the photoresist at the nanosensor region;

(vi) immersing the substrate in an acidic bath to remove the oxide layer at the nanosensor region; and

(vii) immersing the substrate in another acidic bath to remove the hardmask at the nanosensor region (see FIG. 8).

The LTO in step (i) can be conducted by thermal oxidizing the substrate at suitable temperature. Alternatively, the LTO can be deposited using a tetra-ethyl-ortho-silane (TEOS) precursor. Thereinafter, a photoresist is coated over the LTO layer on the nanosensor region. Next, the LTO on the exposed region (CMOS logic circuit region) can be removed by immersing the substrate in a diluted hydrofluoric (HF) acid bath. Subsequently, according to step (iv), the nitride hardmask on the exposed region (CMOS logic circuit region) can be removed by immersing the substrate in a phosphoric acid bath.

General method used in removing photoresist can be applied herein. Thereinafter, there is a step (vi) for immersing the substrate in an diluted hydrofluoric (HF) acid bath so as to remove the thermal oxide layer at the nanosensor region. Subsequently, according to step (vii), the nitride hardmask at the nanosensor region can be removed by immersing the substrate in a phosphoric acid bath.

Preferably, the method further comprising the steps of forming CMOS logic circuit after step (e). The steps of forming CMOS logic circuit includes CMOS well implant, gate formation, spacer formation, source and drain implant, lightly-doped drain (LDD) implant, contact and metallization, but not limited thereto.

The present invention may be embodied in other specific forms without departing from its essential characteristics. The described embodiments are to be considered in all aspects only as illustrative and not restrictive. The scope of the invention is, therefore indicated by the appended claims rather than by the foregoing description. All changes, which come within the meaning and range of equivalency of the claims, are to be embraced within their scope.

What is claimed is:

1. A method for producing a silicon nanosensor integrated with advanced complementary metal oxide semiconductor (CMOS) logic circuit having gate length (Lg) of less than 0.25 μm, comprising the steps of:
allocating a silicon nanosensor region and a complementary metal oxide semiconductor (CMOS) logic circuit region on one bulk silicon substrate;
forming silicon nanowires at the allocated nanosensor region while shielding the CMOS logic circuit region;
applying a layer of protecting hardmask on the substrate such that the hardmask acts as an extra protection layer to the nanosensor region while acting as a hardmask for CMOS logic circuit formation process thereinafter;
subjecting the substrate to selective etching to form trenches, followed by filling the trenches with silicon oxide and subjecting the substrate to chemical mechanical planarization (CMP); and
removing the hardmask from the substrate in a region-by-region manner, in which the nanosensor region remains unexposed while removing hardmark from the CMOS logic circuit region, and vice versa.

2. The method according to claim 1, wherein the step of removing the hardmask from the substrate in a region-by-region manner comprises the steps of:
depositing an oxide layer on the substrate;
shielding the nanosensor region using a photoresist;
immersing the substrate in an acidic bath to remove the oxide layer at the CMOS logic circuit region;
immersing the substrate in another acidic bath to remove the hardmask at the CMOS logic circuit region;
removing the photoresist at the nanosensor region;
immersing the substrate in an acidic bath to remove the oxide layer at the nanosensor region; and
immersing the substrate in another acidic bath to remove the hardmask at the nanosensor region.

3. A silicon nanosensor integrated with an advanced complementary metal oxide semiconductor (CMOS) logic circuit derived from the method according to claim 1.
